(19) United States
(12) Patent Application Publication
(10) Pub. No.: US 2022/0312611 A1
(43) Pub. Date: Sep. 29, 2022

(54) A MOUNTING APPARATUS FOR PROFILES WITH COVER

(71) Applicant: EAE ELEKTRIK AYDINLATMA ENDUSTRISI SANAYI VE TICARET ANONIM SIRKETI, Istanbul (TR)

(72) Inventor: Huseyin AKPINAR, Istanbul (TR)

(21) Appl. No.: 17/286,634

(22) PCT Filed: Nov. 27, 2020
(86) PCT No.: PCT/TR2020/051183

§ 371 Date: Apr. 19, 2021

(30) Foreign Application Priority Data
Dec. 24, 2019 (TR) 2019/21397

(51) Int. Cl. H05K 5/03; H05K 5/02

(52) U.S. Cl. CPC H05K 5/03; H05K 5/0226

(57) ABSTRACT

A mounting apparatus for profiles with a cover that allows simple and quick assembly without using any additional hinge or locking element in products with a lidded structure that can be produced with aluminum profiles.

### TECHNICAL FIELD

The invention relates to a mounting apparatus for profiles with cover.

In particular, the invention relates to a mounting apparatus for profiles with cover that allows a simple and quick assembly process in products with a covered structure that can be produced with aluminum profiles, without using any additional hinges or locking elements.

### BACKGROUND OF THE INVENTION

Aluminum profiles with a covered structure are known as structures that protect the equipment from external factors such as dust, dirt and water. Profiles with cover are frequently used, especially in equipment that must have IP properties.

In the current technique, a structure that functions as a hinge or hinge is required for the opening and closing of the cover mentioned.

Said hinge should be placed on the body evenly so that it can fully fulfill its functional feature. In addition, additional fasteners such as screws must be used in order to perform the assembly of this hinge part.

In order for the hinge to remain stable in the closed state, an additional locking element is required. Within the said locking part, the screw etc. additional fasteners must be used.

In order for this process to be done correctly and properly, both assembly apparatus is required and the assembly process is difficult, causing an increase in the total product cost by increasing the labor cost. In addition, intervention for problems that may occur later in these structures is very difficult and time consuming.

Regarding the subject in the patent application numbered TR 2014 15219 in the literature, “The invention subject to application; It is related to an aluminum side cover profile with a stretch channel, which has been developed to use tensioning tarpaulin fixing mechanisms that allow the internal height of the box to be adjusted by using a single tarpaulin in the tarpaulin trailer type load carrying cases.” statements are included.

In said application, a covered aluminum profile with a hinged structure is disclosed.

Again, in the literature, in the utility model application numbered TR 2018 07688, regarding the subject, “This invention, public buildings, historical buildings, bridges etc. It is about LED lighting with a functional structure that can be used in lighting the exterior of buildings. The body containing the protrusion part and the fixing space, the power supply containing the recess part and the fixing holes, the profile cover positioned on the right and left sides of the power supply, the plastic cover positioned on both ends of the body, the leg fixed to fit the lower part of the body (sliding and adjustable) It consists of a glass part fixed to the right and left sides of the body in such a way that the side lath is fixed to be interlocking, the foot is connected to the bottom and side laths and the plastic cover, which is connected to the top of the foot by the connection elements.” statements are included.

In the said application, a lighting fixture profile is disclosed that allows the assembly of equipment by means of screws.

Again in the literature, in the utility model application numbered TR 2018 11794, regarding the subject, “The inventive linear lighting fixture is mounted by sliding on at least one aluminum body, the cooler profile is mounted on the cooler profile by means of a nail, and the decorative slide body mounted on both ends of the aluminum body and sliding doors. It is a slider body and its feature; the inner size is in accordance with the outer size of the aluminum body and there are sliding channels on both opposite outer sides.” statements are included.

In the said application, a lighting fixture profile with a sliding cover structure is disclosed.

For the reasons mentioned above, a new mounting apparatus was needed for profiles with cover.

### PURPOSE OF THE INVENTION

Based on this state of the art, the purpose of the invention is to introduce a new mounting apparatus for profiles with cover that overcomes the present disadvantages.

Another purpose of the invention is to provide a structure that enables direct manual assembly without using any hand tools such as screw or screwdriver.

Another purpose of the invention is to provide a structure that allows the assembly process to be carried out quickly and prevents the assembled part from being mounted on the body in an offset manner.

Another purpose of the invention is to provide a structure resistant to buckling, pulling and bending.

Another purpose of the invention is to provide a structure with more strength than the screw mounting system.

Another purpose of the invention is to provide a structure that allows assembly and disassembly to be performed with only one person.

Another purpose of the invention is to present a structure that significantly reduces the labor cost.

Another purpose of the invention is to present a structure in which the intervention to problems that may occur later is made easier.

### EXPLANATION OF FIGURES

FIG. 1 A perspective disassembled view of the mounting apparatus for profiles with cover according to the invention

FIG. 2 Another perspective, disassembled view of the mounting apparatus for profiles with cover, according to the invention.

FIG. 3 A perspective view of the mounting apparatus for profiles with cover according to the invention

FIG. 4 Another perspective, disassembled view of the mounting apparatus for profiles with cover according to the invention

FIG. 5 Another perspective view of the mounting apparatus for profiles with cover according to the invention

FIG. 6 A side view of the mounting apparatus for profiles with cover according to the invention

FIG. 7 Another side view of the mounting apparatus for profiles with cover according to the invention

FIG. 8 Another side view of the mounting apparatus for profiles with cover according to the invention

### REFERENCE NUMBERS

A—Mounting Apparatus for Profiles with Cover
1. Hinge Profile
2. Glass Stick
3. Frame Profile
4. Mounting Screw
5. Glass
6. Cover
7. Middle Cover
8. Seal
9. Body Profile
10. Lock Profile
11. Body Head
12. Terminal Cradle

### DETAILED DESCRIPTION OF THE INVENTION

In this detailed description, the innovation subject to the invention is explained only with examples that do not have any limiting effect for better understanding of the subject.

The invention is a mounting apparatus for profiles with cover (A) that allows simple and quick assembly without using any additional hinge or locking element in products with a covered structure that can be produced with aluminum profiles, characterized in that; comprises, the cover (6) that covers the mounting apparatus for profiles with cover (A) and protects against external factors such as dust, dirt, water, the body profile (9) that acts as the main body by accommodating all the units of the mentioned mounting apparatus for profiles with cover (A), the glass (5) formed in the middle of the said cover (6), the hinge profile (1) is positioned as an aluminum profile piece that functions as a hinge to fulfill the opening and closing function when mounted on the body profile (9) of the said cover (6), and also fulfills the function of terminating a horizontal edge of said glass (5), frame profile (3) is positioned parallel to the hinge profile (1) on the opposite edge of the hinge profile (1) where the said hinge profile (1) terminates the glass (5) as another termination element of the said glass (5), and is also positioned as the end that fulfills the function of locking the said cover (6) and the lock profile (10) performing the function of locking by bearing the frame profile (3) by closing the said cover (6) on the body profile (9).

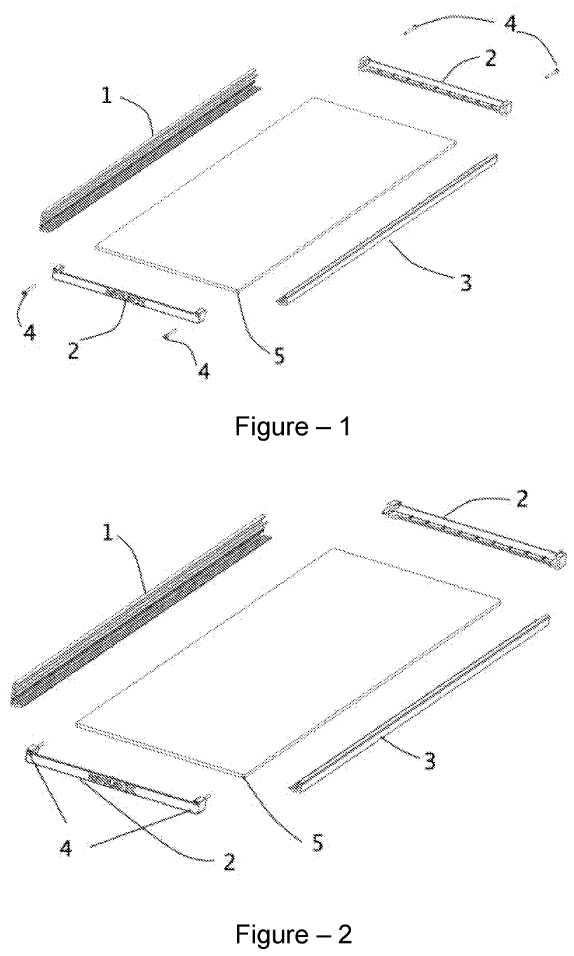

FIG. 1 shows a perspective disassembled view of the mounting apparatus for profiles with cover (A) according to the invention.

FIG. 2 shows another perspective, disassembled view of the mounting apparatus for profiles with cover (A) according to the invention.

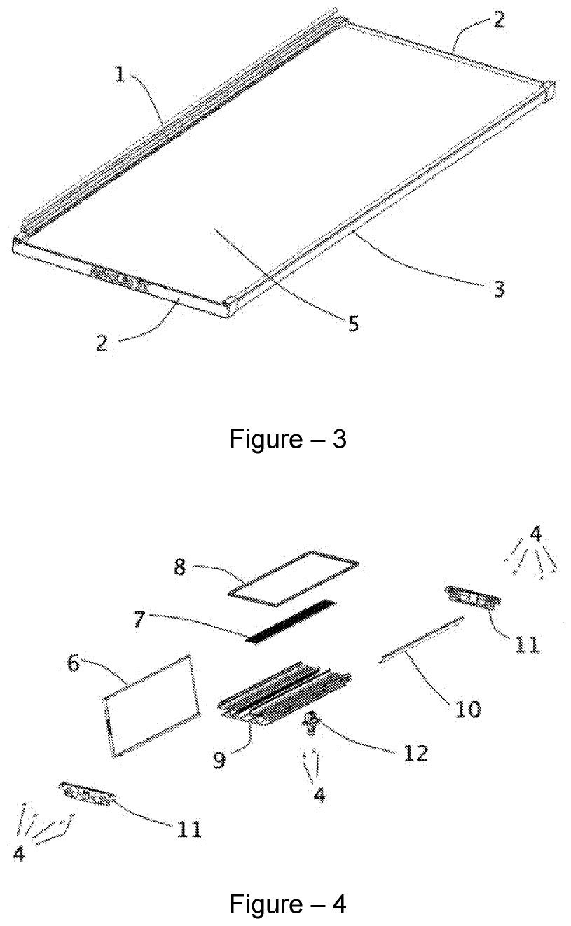

FIG. 3 shows a perspective view of the mounting apparatus for profiles with cover (A) according to the invention.

FIG. 4 shows another perspective, disassembled view of the mounting apparatus for profiles with cover (A) according to the invention.

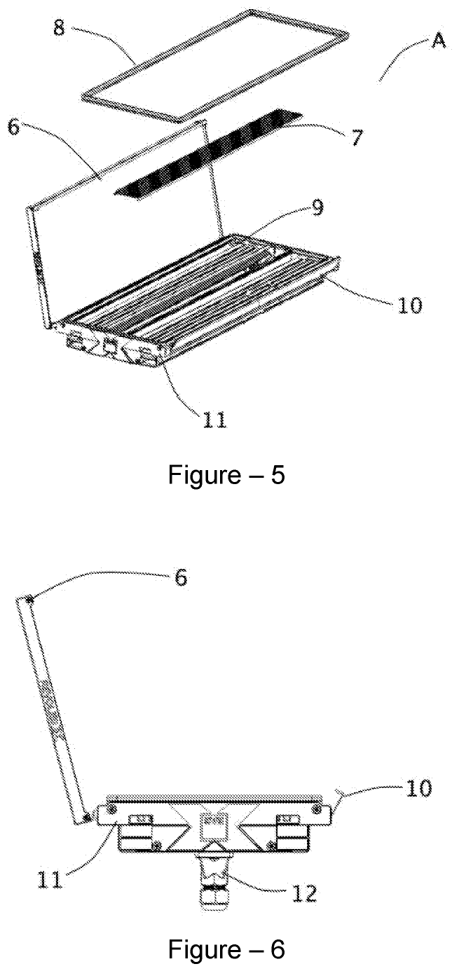

FIG. 5 shows another perspective view of the mounting apparatus for profiles with cover (A) according to the invention.

FIG. 6 shows a side view of the mounting apparatus for profiles with cover (A) according to the invention.

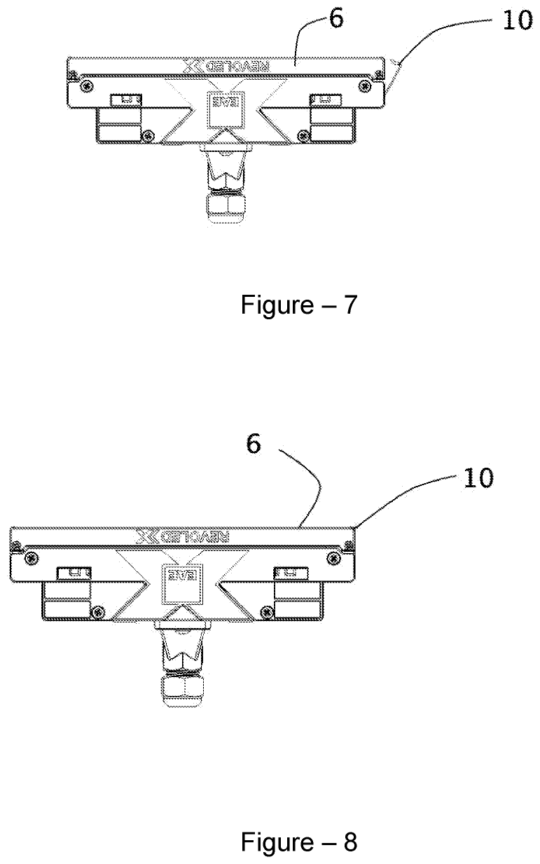

FIG. 7 shows another side view of the mounting apparatus for profiles with cover (A) according to the invention.

FIG. 8 shows another side view of the mounting apparatus for profiles with cover (A) according to the invention.

Mounting apparatus for profiles with cover (A) according to the invention, consists main parts of the cover (6) that covers the mounting apparatus for profiles with cover (A) and protects against external factors such as dust, dirt, water, the body profile (9) that acts as the main body by accommodating all the units of the mentioned mounting apparatus for profiles with cover (A), the glass (5) formed in the middle of the said cover (6), the hinge profile (1) is positioned as an aluminum profile piece that functions as a hinge to fulfill the opening and closing function when mounted on the body profile (9) of the said cover (6), and also fulfills the function of terminating a horizontal edge of said glass (5), glass stick (2) positioned on the right and left sides of the said glass (5) as right and left termination elements, frame profile (3) is positioned parallel to the hinge profile (1) on the opposite edge of the hinge profile (1) where the said hinge profile (1) terminates the glass (5) as another termination element of the said glass (5), and is also positioned as the end that fulfills the function of locking the said cover (6), mounting screws (4) that allow the equipment to be mounted on each other, the middle cover (7) positioned as a cover covering the materials in the middle part of the mounting apparatus for profiles with cover (A), seal (8) providing IP protection of the mounting apparatus for profiles with cover (A), the lock profile (10) performing the function of locking by bearing the frame profile (3) by closing the said cover (6) on the body profile (9), the body head (11) positioned as the termination element of the said body profile (9), the terminal cradle (12) positioned as the part that provides the electrical connection of the mounting apparatus for profiles with cover (A).

In the practice of the invention, the mounting screws (4) are placed in the mounting slots on the glass stick (2). Afterwards, the frame profile (3) and the hinge profile (1) are placed on the long right and left edges of the glass (5).

Afterwards, the glass stick (2) is placed on the short edges of the glass (5) and the cover (6) assembly process is completed by tightening the mounting screws (4). After the assembly of the mentioned cover (6), the product assembly is started.

For this process, firstly, the lock profile (10) is pushed into the channel on the body profile (9). Later, the cover (6) is pushed by sliding into the channel on the body profile (9).

For the next process, the body head (11) is mounted to the body profile (9) with mounting screws (4) from the side of the body profile (9). Later, the other body head (11) is mounted from the other side of the body profile (9) with mounting screws (4).

Afterwards, the terminal cradle (12) is placed in its slot on the back part of the body profile (9) and mounted to the body profile (9) with mounting screws (4).

Subsequently, the middle cover (7) is mounted to the area in the middle of the body profile (9) thanks to its nailed structure. The seal (8) is mounted on the seal seat on the body profile (9).

After this stage, the cover (6) is closed thanks to its seat on the body profile (9). Later, the lock profile (10) functions as a lock thanks to its seat on the body profile (9) and is locked by fitting into its slot on the cover (6). Thanks to this locking, the body falls under the IP protection class.

1. A mounting apparatus for profiles with a cover (A) that allows simple and quick assembly without using any additional hinge or locking element in products with a covered structure that can be produced with aluminum profiles, characterized in that; it comprises: a cover (6) that covers the mounting apparatus for profiles with cover (A) and protects against external factors such as dust, dirt, water, a body profile (9) that acts as the main body by accommodating all the units of the mentioned mounting apparatus for profiles with cover (A), glass (5) formed in the middle of the said cover (6), a hinge profile (1) is positioned as an aluminum profile piece that functions as a hinge to fulfill the opening and closing function when mounted on the body profile (9) of the said cover (6), and also fulfills the function of terminating a horizontal edge of said glass (5), a frame profile (3) is positioned parallel to the hinge profile (1) on the opposite edge of the hinge profile (1) where the said hinge profile (1) terminates the glass (5) as another termination element of the said glass (5), and is also positioned as the end that fulfills the function of locking the said cover (6) and the lock profile (10) performing the function of locking by bearing the frame profile (3) by closing the said cover (6) on the body profile (9).

2. A mounting apparatus for profiles with cover (A) according to claim 1, comprising a glass stick (2) positioned on the right and left sides of the said glass (5) as right and left termination elements.

3. A mounting apparatus for profiles with cover (A) according to claim 1, comprising a middle cover (7) positioned as a cover covering the materials in the middle part of the mounting apparatus for the profiles with cover (A).

4. A mounting apparatus for profiles with cover (A) according to claim 1, wherein a seal (8) provides IP protection of the mounting apparatus for the profiles with cover (A).
